(19) United States
(12) Patent Application Publication
(10) Pub. No.: US 2026/0265936 A1
(43) Pub. Date: Sep. 10, 2026

(54) ELECTROCHEMICAL CATALYST COMPOSITION FOR HYDROGEN PEROXIDE PRODUCTION INCLUDING MOLYBDENUM PHOSPHIDE CRYSTAL AND METHOD FOR MANUFACTURING THE SAME

(71) Applicant: SUNGSHIN WOMEN'S UNIVERSITY R&DB FOUNDATION, Seoul (KR)

(72) Inventors: Hyeuk Jin HAN, Seoul (KR); Seo Hyun KIM, Seoul (KR); Jeong Hyun KIM, Seoul (KR); Min Jae CHOI, Seoul (KR)

(21) Appl. No.: 19/557,434

(22) Filed: Mar. 5, 2026

(30) Foreign Application Priority Data
Mar. 6, 2025 (KR) 10-2025-0028750

(51) Int. Cl. C25B 11/075; C25B 1/30; C25B 11/052; C25B 11/061; C30B 25/18; C30B 29/10; C30B 29/64; C30B 29/66

(52) U.S. Cl. CPC C25B 11/075; C25B 11/052; C25B 11/061; C30B 25/18; C30B 29/10; C30B 29/64; C30B 29/66; C25B 1/30

(57) ABSTRACT

The present invention relates to an electrochemical catalyst composition for hydrogen peroxide production including a molybdenum phosphide crystal and a method for manufacturing the same. The molybdenum phosphide crystal of the present invention is in a single crystal state, and has a controlled crystal plane, and thus has the advantage of being usable as an excellent electrochemical catalyst for hydrogen peroxide production. In addition, the manufacturing method of the present invention applies a liquid-metal-assisted chemical vapor deposition method with an optimized temperature to control a crystal plane, and thus has the advantage of being able to rapidly grow and obtain a molybdenum phosphide single crystal usable as an electrochemical catalyst for hydrogen peroxide production.

### CROSS-REFERENCE TO RELATED APPLICATION

This application claims priority to Korean Patent Application No. 10-2025-0028750 filed on Mar. 6, 2025 and all the benefits accruing therefrom under 35 U.S.C. § 119, the contents of which are incorporated by reference in their entirety.

### BACKGROUND

The present disclosure relates to an electrochemical catalyst composition for hydrogen peroxide production including a molybdenum phosphide crystal and a method for manufacturing the same.

A transition metal phosphide is a compound in which a transition metal and phosphorus are bonded to each other, and is used in various applications such as a battery, a low-loss interconnection, and a catalyst. Examples of the transition metal phosphide include a nickel phosphide (Ni₃P, Ni₅P₂, Ni₂P, Ni₃P₂, Ni₂P₃, NiP₃, or NiP₃), a cobalt phosphide (Co₂P, Co₃P₂, Co₄P₃, Co₂P₃, CoP, or CoP₃), an iron phosphide (Fe₃P, Fe₂P, FeP, FeP₂, Fe₅P₂, Fe₃P₂, Fe₄P₃, Fe₅P₄, or Fe₂P₃), and a molybdenum phosphide (MoP₂, MoP, or Mo₃P), and among the molybdenum phosphides, a molybdenum phosphide (MoP) is characterized by having high thermal conductivity and electrical conductivity. The molybdenum phosphide has properties of exhibiting excellent catalytic activity and stability in various electrolytic environments, and thus is attracting attention as a material that can be used as an efficient electrochemical catalyst in a hydrogen generation reaction including a two-electron transfer process, or that can be utilized in high-performance electronic fields related to energy. In order to utilize the molybdenum phosphide (MoP), it is preferable that the molybdenum phosphide (MoP) is manufactured in a single crystal form. This is because the molybdenum phosphide (MoP) single crystal has no interference from grain boundaries or defects compared to when in a multi-crystal state, thereby allowing for a variety of applications through evaluation of material properties.

An ion-mediated synthesis method or a sol-gel method is known as a method for manufacturing a molybdenum phosphide crystal. However, this method has the limitation in that the molybdenum phosphide crystal has a multi-crystal structure. A chemical vapor transport (CVT) method and a chemical vapor deposition (CVD) method are known as methods for manufacturing molybdenum phosphide in a single crystal state. However, these methods have limitations in that the growth rate of crystals is slow, resulting in a limited yield rate, and the control of a crystal plane is difficult, resulting in limited performance.

The patent literature and references cited herein are incorporated by reference herein to the same extent that each document is individually and clearly identified by reference.

### PRIOR ART DOCUMENTS

### Patent Documents

(Patent Document 1) Korean Patent Laid-Open Publication No. 10-2023-0026010

### SUMMARY

The present disclosure experimentally has confirmed that when a manufacturing method using a liquid-metal-assisted chemical vapor deposition method is applied to a molybdenum phosphide crystal, which has a slow crystal growth rate and difficulty in controlling a crystal plane, and thus has limitations in its use as a catalyst for hydrogen peroxide production, the molybdenum phosphide crystal not only rapidly grows into a single crystal state, but also has a controlled crystal plane, thereby having improved hydrogen peroxide production performance.

Therefore, the present disclosure provides a molybdenum phosphide crystal synthesized using a liquid-metal-assisted chemical vapor deposition method with an optimized temperature, an electrochemical catalyst composition for hydrogen peroxide production including the same, and a manufacturing method thereof.

Other objects and technical features of the present invention are presented in more detail by a detailed description of the invention, claims, and drawings below.

In accordance with an exemplary embodiment, an electrochemical catalyst composition for hydrogen peroxide production including a molybdenum phosphide crystal is provided.

The electrochemical catalyst composition may be characterized by including a molybdenum phosphide crystal, an organic solvent, deionized water, and an ionomer.

The molybdenum phosphide crystal may be characterized by being a molybdenum phosphide (MoP) single crystal having an atomic ratio of phosphorus to molybdenum of 1:1, and the molybdenum phosphide crystal is characterized by being either a molybdenum phosphide (MoP) pillar single crystal having a (101̅1) surface, or a molybdenum phosphide (MoP) nanoplate single crystal having a (0001) surface.

The molybdenum phosphide crystal may be characterized by being synthesized by a manufacturing method including a first process of placing a gallium droplet on molybdenum to prepare a gallium-molybdenum substrate, a second process of heating the gallium-molybdenum substrate to 650° C. to 1100° C., and a third process of flowing phosphorus heated to 300° C. to 600° C. over the heated gallium-molybdenum substrate under the condition of a 40 sccm to 300 sccm argon gas or hydrogen gas flow to manufacture a molybdenum phosphide crystal.

The exemplary embodiment may be characterized in that when the gallium-molybdenum substrate of the second process is heated to 650° C. to 850° C., a molybdenum phosphide pillar single crystal having a (101̅1) surface is manufactured, and when the gallium-molybdenum substrate of the second process is heated to 900° C. to 1100° C., a molybdenum phosphide (MoP) nanoplate single crystal having a surface is manufactured.

### BRIEF DESCRIPTION OF THE DRAWINGS

Exemplary embodiments can be understood in more detail from the following description taken in conjunction with the accompanying drawings, in which:

FIG. 1 shows a process of manufacturing a molybdenum phosphide (MoP) single crystal in accordance with an exemplary embodiment;

FIG. 2 shows results of scanning electron microscopy analysis, X-ray diffraction analysis, energy spectroscopy analysis, Raman spectroscopy analysis, and X-ray photoelectron spectroscopy analysis performed on a molybdenum phosphide single crystal in accordance with an exemplary embodiment;

FIG. 3 shows results of analyzing electrochemical oxygen reduction reaction performance related to hydrogen peroxide production according to a crystal plane of a molybdenum phosphide single crystal in accordance with an exemplary embodiment; and

FIG. 4 shows results of using a molybdenum phosphide pillar single crystal in accordance with another exemplary embodiment as an electrocatalyst for hydrogen peroxide production in an H-cell.

### DETAILED DESCRIPTION

An exemplary embodiment provides an electrochemical catalyst composition for hydrogen peroxide production including a molybdenum phosphide crystal.

The molybdenum phosphide may be MoP₂, MoP, or Mo₃P, preferably MoP. In addition, the molybdenum phosphide crystal of the exemplary embodiment may also be a single crystal of molybdenum phosphide, preferably a single crystal of MoP. The single crystal of MoP has an atomic ratio of phosphorus to molybdenum of 1:1.

The molybdenum phosphide crystal of the exemplary embodiment is characterized by being either a molybdenum phosphide (MoP) pillar single crystal having a (101̅1) surface, or a molybdenum phosphide (MoP) nanoplate single crystal having a (0001) surface.

The electrochemical catalyst composition for hydrogen peroxide production including the molybdenum phosphide crystal of the exemplary embodiment is characterized by including a molybdenum phosphide crystal, an organic solvent, deionized water, and an ionomer, and preferably, a molybdenum phosphide single crystal is used as the molybdenum phosphide crystal, isopropanol is used as the organic solvent, and Nafion is used as an ionomer.

The electrochemical catalyst composition for hydrogen peroxide production including the molybdenum phosphide crystal of the exemplary embodiment may be prepared by mixing the molybdenum phosphide crystal, the organic solvent, the deionized water, and the ionomer to prepare a catalyst slurry, and subjecting the catalyst slurry to ultrasonic treatment, and the prepared electrochemical catalyst composition may be coated to an appropriate thickness on an electrode or Teflon-treated carbon fiber paper to be used as an electrochemical catalyst for hydrogen peroxide production.

The molybdenum phosphide crystal of the exemplary embodiment may be manufactured using a liquid-metal-assisted chemical vapor deposition method with an optimized temperature. The molybdenum phosphide crystal of the exemplary embodiment is characterized by being manufactured by a manufacturing method including a first process of placing a gallium droplet on molybdenum to prepare a gallium-molybdenum substrate, a second process of heating the gallium-molybdenum substrate to 650° C. to 1100° C., and a third process of flowing phosphorus heated to 300° C. to 600° C. over the heated gallium-molybdenum substrate under the condition of a 40 sccm to 300 sccm argon gas or hydrogen gas flow to manufacture a molybdenum phosphide crystal.

The exemplary embodiment is characterized in that when the gallium-molybdenum substrate of the second process is heated to 650° C. to 850° C., a molybdenum phosphide (MoP) pillar single crystal having a (101̅1) surface is manufactured, and is characterized in that when the gallium-molybdenum substrate is heated to 900° C. to 1100° C., a molybdenum phosphide (MoP) nanoplate single crystal having a (0001) surface is manufactured. If the temperature is out of the above-described range, a crystal surface is not controlled, so that the molybdenum phosphide (MoP) pillar single crystal having the (101̅1) surface or the molybdenum phosphide (MoP) nanoplate single crystal having the (0001) surface may not be synthesized.

Hereinafter, the present invention will be described in detail with reference to examples.

### EXAMPLES

### 1. Experimental Method

### 1) Manufacturing of Molybdenum Phosphide Single Crystal

In the exemplary embodiment, a molybdenum phosphide (MoP) single crystal was manufactured using a liquid-metal-assisted chemical vapor deposition method. A gallium (Ga, Alpha Aesar, >99.9% purity) pellet was prepared in the form of a droplet as a growth substrate, and molybdenum (Mo, 99.95 wt % purity) foil was cleaned with ethanol and prepared. The prepared gallium droplet was placed on the molybdenum foil to manufacture a gallium-molybdenum substrate, which was then heated to 650° C. to 1100° C. at a temperature raising rate of 30° C./min in a quartz tube. Red phosphorus powder (P, Alpha Aesar, >99.9% purity) was placed in the quartz tube, and the temperature was maintained at 300° C. to 600° C. The heated red phosphorus was introduced to the heated gallium-molybdenum substrate for 30 minutes under conditions of a 250 sccm argon gas flow and a 50 sccm hydrogen gas flow to grow a molybdenum phosphide (MoP) single crystal.

### 2) Characteristics Analysis of Molybdenum Phosphide Single Crystal

Scanning electron microscopy (ZEISS Merlin Compact SEM) analysis and X-ray photoelectron spectroscopy (XPS, Thermo Scientific, ESCALAB 250Xi, monochromatic Al Kα radiation) analysis were performed on the manufactured molybdenum phosphide (MoP) single crystal.

Elemental mapping for the manufactured molybdenum (MoP) single crystal was performed using energy-dispersive X-ray spectroscopy (EDS) analysis.

Raman spectrometer analysis was performed at room temperature under conditions of a laser with a wavelength of 532 nm, a beam with a diameter of 1 μm, and a magnification of 40 times. The Raman spectra were recorded using a lattice with 1,800 grooves/mm, and were corrected using the Raman peak of silicon (Si) at 521 cm⁻¹. XRD measurement was performed using an X-ray diffractometer (D8 FOCUS; Bruker).

Absorbance spectra were analyzed at room temperature using a JASCO V-770 spectrophotometer with an 808 nm laser.

EBSD images were collected using an environmental scanning electron microscope (Quattro S, Thermo Fisher) equipped with an EDAX Velocity EBSD camera.

### 2) Electrochemical Characteristics Analysis of Molybdenum Phosphide Single Crystal

In the exemplary embodiment, a molybdenum phosphide (MoP) single crystal is used as an electrochemical catalyst for hydrogen peroxide production. Therefore, an electrochemical catalyst ink composition including the molybdenum phosphide (MoP) single crystal of the exemplary embodiment was prepared, which was then used to manufacture an electrode, and then hydrogen peroxide (H₂O₂) production properties were analyzed.

The electrochemical analysis was performed in a three-electrode cell equipped with a rotating ring-disk electrode (RRDE) setup and an autolab potentiostat (PGSTAT302N). A working electrode (WE) of the RRDE was composed of a glassy carbon disk (area: 0.196 cm²) and a platinum ring electrode, and mechanically polished using alumina powder and then washed with deionized water to be used.

3 mg of the molybdenum phosphide (MoP) single crystal (electrochemical catalyst) of the exemplary embodiment, 0.475 μL of isopropanol, 1.425 μL of deionized water (D.W.), and 50 μL of a 5% Nafion solution were mixed to prepare a catalyst slurry, which was then subjected to ultrasonic treatment for 25 minutes to prepare a molybdenum phosphide (MoP) single-crystal electrochemical catalyst ink. The molybdenum phosphide (MoP) single-crystal electrochemical catalyst ink was loaded on the working electrode at a rate of 20 μg/cm², and the thickness of the molybdenum phosphide (MoP) single-crystal electrochemical catalyst ink was adjusted to be sufficiently thin to allow produced hydrogen peroxide to be detected at the ring electrode.

In order to test the hydrogen peroxide production performance of a molybdenum phosphide (MoP) single-crystal electrochemical catalyst of the exemplary embodiment, pre-cycling (10 cycles at a scan rate of 0.1 V/s and a scan range of 0.05 V to 1.0 V in Ar-saturated 0.1 M KOH solution) was performed using cyclic voltammetry (CV) and the surface of the platinum ring was washed using CV (scan rate of 0.5 V/s, scan range of 0.05 V to 1.0 V, and 20 cycles).

The hydrogen peroxide production rate and selectivity of the molybdenum phosphide (MoP) single-crystal electrochemical catalyst of the exemplary embodiment were measured under oxygen (O₂)-saturated electrolyte conditions of a scan rate of 0.01 V/s and a rotation speed of 1,600 rpm. The platinum ring electrode was maintained at 1.2 V (vs. RHE) so as to be set to be oxidized by hydrogen peroxide produced at the disk electrode.

An oxygen reduction reaction (ORR) current was corrected by subtracting a current obtained under argon (Ar)-saturated electrolyte conditions from a current measured under the oxygen (O₂)-saturated electrolyte conditions, and a ring current was corrected using RRDE collection efficiency to quantify the hydrogen peroxide production.

The RRDE collection efficiency was determined using a potassium hexacyanoferrate (III) solution (N=0.278), and the collection efficiency, selectivity, 2e⁻ mass activity, turnover frequency (TOF), and kinetic current density were calculated using Equations 1 to 5 below.

$$Selectivity ( \% ) = \frac{200 \times ( {I}_{r} / N )}{( {I}_{d} + {I}_{r} / N )} \qquad ( Equation 1 )$$

$$2 {e}^{-} mass activity = \frac{Ring current density [ A / {cm}^{2} ]}{Catalyst loading density [ g / {cm}^{2} ]} \qquad ( Equation 2 )$$

$$Turnover frequency [ {s}^{- 1} ] = \frac{number of oxygen molecules turnover}{number of active sites} \qquad ( Equation 3 )$$

$$Number of oxygen molecules turned over = j [ \frac{mA}{{cm}^{2}} ] \times \frac{1 [ \frac{C}{s} ]}{1 , 000 [ mA ]} \times \frac{1 [ mol {e}^{-} ]}{96485 [ C ]} \times \frac{1 [ mol {O}_{2} ]}{2 [ mol {e}^{-} ]} \times ( 6.02 \times {10}^{23} [ \frac{atom {O}_{2}}{Mol {O}_{2}} ] ) \qquad ( Equation 4 )$$

$$Number of active sites = L [ \frac{mg}{cm2} ] \times R [ wt \% ] \times \frac{1 [ mmol ]}{W [ mg ]} \times ( 6.02 \times {10}^{20} [ \frac{atom}{mmol} ] ) \qquad ( Equation 5 )$$

In Equation 1 above, the Iᵣ represents a ring current, the Id represents a disc current, and N represents a current collection efficiency (0.278). The variable represents a current density according to hydrogen peroxide production. The current density is measured through a ring electrode by using the collection efficiency of a rotating ring disc electrode setup under given overpotential conditions. In addition, the L (0.02 mg/cm²) represents an amount of catalyst loaded on an electrode; the R (0.244 wt %) represents a weight fraction; and the W (30.97 mg) represents an atomic weight of an active site element.

$$\cdot {j}_{k} = \frac{j \times {j}_{d}}{{j}_{d} - j} \qquad ( Equation 6 )$$

$$\cdot \frac{1}{j} = \frac{1}{{j}_{k}} + \frac{1}{0.62 {nFC}_{0} ( {D}_{0} ) 2 / 3 {v}^{- 1 / 6} {w}^{1 / 2}} \qquad ( Equation 7 )$$

In the above equation, the jₖ represents a kinetic current density; the j represents a measured current density; the w represents an angular velocity; the n represents an electron transfer number; the F represents a Faraday constant (96485 C/mol); the Co represents an O₂ saturation concentration (1.1×10⁻⁶ mol/cm³) of an electrolyte at room temperature; the D₀ represents an O₂ diffusion coefficient (1.9×10⁻⁵ cm²/s) of an electrolyte; and the v is a kinematic viscosity (1×10⁻² cm²/s) of an electrolyte at 25° C.

### 4) Measurement of Hydrogen Peroxide Production Amount by Using H-Cell System

An amount of hydrogen peroxide produced using the molybdenum phosphide (MoP) single-crystal electrochemical catalyst of the exemplary embodiment was measured. To this end, a two-compartment H-cell system using a Nafion 117 membrane and a molybdenum phosphide (MoP) single-crystal electrochemical catalyst were used.

The H-cell system used Ag/AgCl as a reference electrode; a graphite rod was used as a CE; Teflon-treated carbon fiber paper (0.5×0.5 cm²) modified with a molybdenum phosphide (MoP) single crystal was used as a WE; a mass loading rate was set to 0.1 mg/cm²; and a positive electrode (50 mL) and a positive electrode compartment were filled with the same electrolyte.

Concentration of the produced hydrogen peroxide was analyzed using a colorimetric method. To this end, a linear calibration curve for the range of 0.1 mM to 0.4 mM of hydrogen peroxide was prepared. The linear calibration curve was prepared by reacting a 0.1 mM to 0.4 mM hydrogen peroxide solution with 3.8 ml of a 0.1 M acidified titanium sulfate to prepare a H₂TiO₄ standard solution, and measuring absorbance (407 nm) using an ultraviolet-visible spectrophotometer.

The amount of hydrogen peroxide produced using the molybdenum phosphide (MoP) single-crystal electrochemical catalyst of the exemplary embodiment was calculated by reacting 0.2 ml of collected electrolyte with 3.8 ml of a 0.1 M acidified titanium sulfate solution, measuring absorbance (407 nm), and then comparing the measurement result with the linear calibration curve prepared above.

Total charge flux passing through an electrode was integrated over time to analyze Faradaic Efficiency (FE) according to the production of hydrogen peroxide, and the efficiency of continuously producing hydrogen peroxide, that is, robustness as an electrochemical catalyst, was evaluated using chronoamperometry.

Productivity of hydrogen peroxide using the molybdenum phosphide (MoP) single-crystal electrochemical catalyst of the exemplary embodiment was calculated by the following equations.

$$FE = 2 \times {C}_{{H}_{2} {O}_{2}} \times F \times \frac{V}{Q} \times 100 \% \qquad ( Equation 8 )$$

$${H}_{2} {O}_{2} productivity [ mmol {h}^{- 1} {g}^{- 1} ] = {C}_{{H}_{2} {O}_{2}} \times V \times \frac{{10}^{3}}{a \times m \times t} \qquad ( Equation 9 )$$

In Equations 8 and 9 above, the C_{H2O2} represents the concentration of hydrogen peroxide (H₂O₂=0.00035797 mol/L); the F represents a Faraday constant (96485.3 C/mol); the V represents an electrolyte volume (0.5 L); the Q represents an accumulated charge (4.70208 C); the A represents an electrode area (0.5 cm²); the m represents a catalyst mass load (0.1 mg/cm²); and the t represents reaction time (1 hr).

### 2. Experimental Results

1) Manufacturing of Molybdenum Phosphide Single Crystal with Controlled Crystal Plane

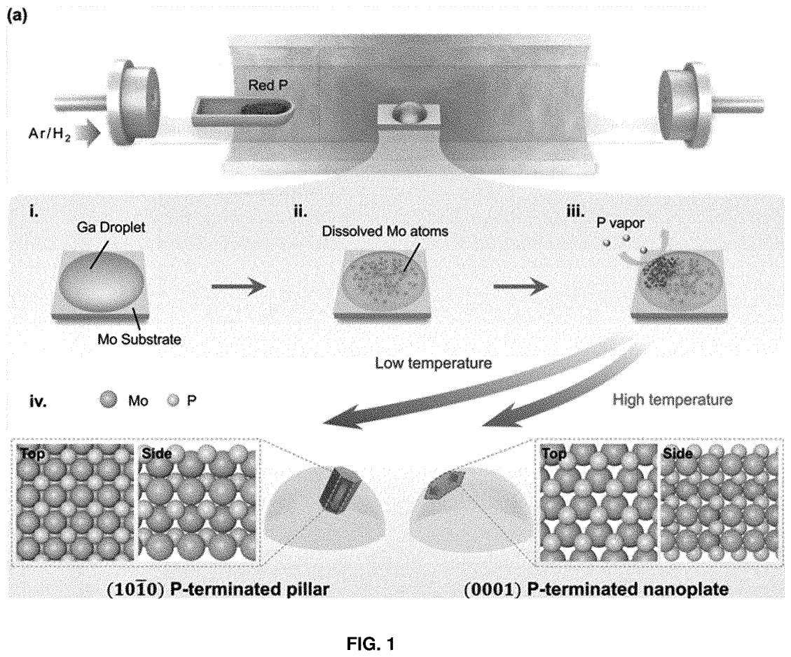

FIG. 1 shows a process of manufacturing a molybdenum phosphide (MoP) single crystal of the exemplary embodiment. Panel (a) shows that a molybdenum (MoP) single crystal grows in a horizontal tube furnace through a chemical vapor deposition process; and Panel (b) schematically shows mechanisms (steps (i) to (iv)) in which a molybdenum phosphide (MoP) single crystal is formed. Step (i) of Panel (b) schematically shows that a gallium (Ga) droplet is positioned on a molybdenum (Mo) substrate; Step (ii) of Panel (b) schematically shows that molybdenum atoms are diffused into the gallium droplet; Step (iii) of Panel (b) schematically shows that red phosphorus vapor is introduced into the gallium droplet during a chemical vapor deposition process; and Step (iv) of Panel (b) schematically shows the structure of a molybdenum phosphide (MoP) single crystal is formed according to a synthesis temperature. When the synthesis temperature is high (900° C.), it was confirmed that a molybdenum phosphide (MoP) nanoplate (or phosphorous-terminated nanoplate) single crystal having a (EN surface was synthesized, and when it is low (700° C.), it was confirmed that a molybdenum phosphide (MoP) pillar (or phosphorous-terminated pillar) single crystal having a t surface was synthesized.

The molybdenum phosphide (MoP) single crystal of the exemplary embodiment is synthesized using a liquid-metal-assisted chemical vapor deposition (CVD) method (see FIG. 1). Molybdenum foil was used as a support for gallium and molybdenum elements, which are substrates, and red phosphorus (Red P) was used as a phosphorus element.

When heat is applied, the surface energy increases, causing molybdenum to diffuse to the surface of a gallium droplet, and the diffused molybdenum reacts with phosphorus on the surface of gallium to form molybdenum phosphide. When a crystal having a specific structure is grown in a process of synthesizing molybdenum phosphide and growing crystals, structural and functional properties of the molybdenum phosphide are determined.

According to the exemplary embodiment, it was confirmed that when the synthesis was performed at a high temperature of 900° C., the molybdenum phosphide nanoplate single crystal having the (0001) surface was synthesized, when the synthesis was performed at a relatively low temperature of 700° C., the molybdenum phosphide pillar single crystal having the (101̅1) surface was synthesized.

In the exemplary embodiment, in order to control the crystal plane of a molybdenum phosphide single crystal, the surface energy of various planes was calculated and analyzed. An increase in the synthesis temperature causes phosphorus to be disposed according to stability on the surface reflecting chemical activity.

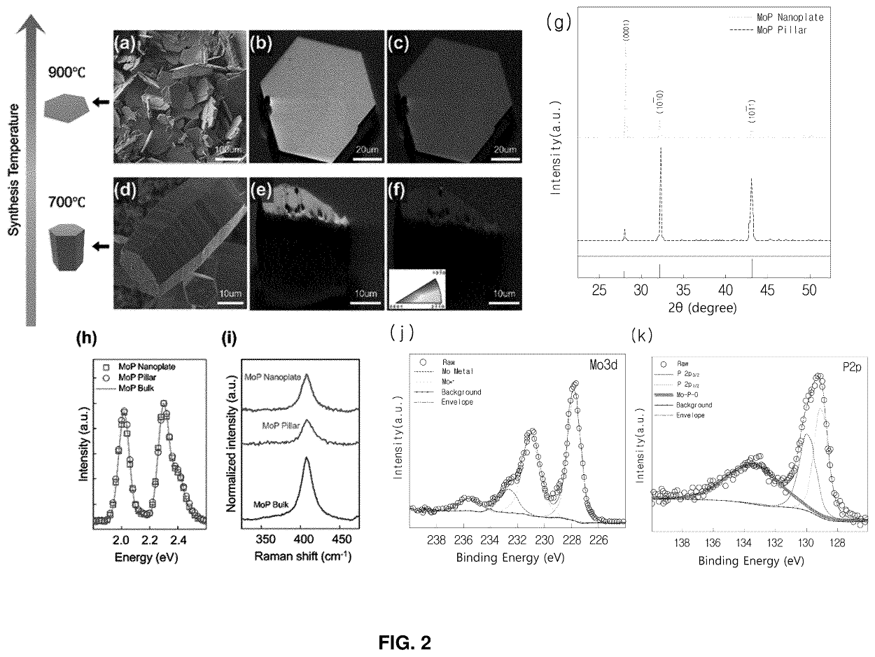

Under the condition of a synthesis temperature of 900° C., a molybdenum phosphide single crystal has a (0001) surface as a crystal plane (crystal plane), and this is because under the synthesis temperature condition, phosphorus grows on a phosphorus-terminated (0001) surface, which has the lowest surface energy compared to other surfaces. The synthesis temperature determines the thermodynamic stability of a crystal plane and determines the production and rate of a nucleus. In order to confirm the above, the relationship between a synthesis temperature and a crystal shape was analyzed. As a result of the analysis, it was confirmed that at a synthesis temperature of 900° C., a surface reaction is accelerated to increase a growth rate, resulting in forming a molybdenum nanoplate single crystal oriented along a (0001) plane (see FIG. 2).

In addition, under the condition of a synthesis temperature of 900° C., a surface growth rate decreases due to changes in dynamic factors, resulting in forming many small surfaces and vertical surfaces, so that a (101̅0) surface shape similar to a pillar structure appears (see FIG. 2).

FIG. 2 shows results of scanning electron microscopy analysis, X-ray diffraction analysis, energy spectroscopy analysis, Raman spectroscopy analysis, and X-ray photoelectron spectroscopy analysis performed on the molybdenum phosphide single crystal of the exemplary embodiment. Panels (a) and (b) of FIG. 2 show scanning electron microscope images of a molybdenum phosphide single crystal synthesized at a synthesis temperature of 900° C.; and Panel (c) of FIG. 2 shows a result of electron backscatter diffraction (EBSD) analysis of the molybdenum phosphide single crystal synthesized at a synthesis temperature of 900° C. As a result of the analysis, it was confirmed that the molybdenum phosphide single crystal synthesized at a synthesis temperature of 900° C. has a hexagonal nanoplate and a smooth (0001) surface.

Panels (d) and (e) of FIG. 2 show scanning electron microscope images of a molybdenum phosphide single crystal synthesized at a synthesis temperature of 700° C.; and Panel (f) of FIG. 2 shows a result of electron backscatter diffraction (EBSD) analysis of the molybdenum phosphide single crystal synthesized at a synthesis temperature of 700° C. As a result of the analysis, it was confirmed that the molybdenum phosphide single crystal synthesized at a synthesis temperature of 700° C. has a long pillar structure and a (101̅0) surface shape.

Panel (g) of FIG. 2 shows a result of X-ray diffraction analysis of the molybdenum phosphide single crystals synthesized at a synthesis temperature of 900° C. and 700° C.; Panel (h) shows results of energy spectroscopy analysis of molybdenum phosphide single crystals (MoP nanoplate and MoP pillar) synthesized using a liquid-metal-assisted chemical vapor deposition method of the exemplary embodiment, and a molybdenum phosphide single crystal (MoP bulk) synthesized using a chemical vapor transport (CVT) method; Panel (i) shows a result of Raman spectroscopy analysis of the molybdenum phosphide single crystal of the exemplary embodiment; and Panels (j) and (k) show results of X-ray photoelectron spectroscopy analysis.

As a result of analyzing the crystal structure of the molybdenum phosphide single crystal of the exemplary embodiment, a diffraction peak (JCPDS card No. 65-6024) according to structural characteristics of molybdenum phosphide was confirmed. Therefore, when the intensity of a (0001) peak of a molybdenum phosphide nanoplate single crystal is compared with the intensity of a (101̅0) peak of a molybdenum phosphide pillar single crystal, it is possible to confirm in which direction the crystals have grown.

Panel (h) of FIG. 2 shows results of energy spectroscopy analysis of the molybdenum phosphide single crystals (MoP nanoplate and MoP pillar) synthesized using a liquid-metal-assisted chemical vapor deposition method of the exemplary embodiment, and the molybdenum phosphide single crystal (MoP bulk) synthesized using a chemical vapor transport (CVT) method. The molybdenum phosphide nanoplate single crystal and the molybdenum phosphide pillar single crystal of the exemplary embodiment were confirmed to have an atomic ratio of molybdenum to phosphorus (Mo:P) of 1:1.

As a result of Raman spectrum analysis, the molybdenum phosphide single crystal of the exemplary embodiment was confirmed to have a new peak at 409 cm⁻¹, and as a result of calculation, there was no inversion symmetry in an E mode, confirming Raman activity (see Panel (i) of FIG. 2). The above results indicate that the synthesized molybdenum phosphide single crystal of the exemplary embodiment share structural properties with a typical molybdenum phosphide material, and that the manufacturing method of the exemplary embodiment is effective not only in growing a molybdenum phosphide single crystal but also in controlling a crystal plane.

A surface electron state was analyzed for an element present in the molybdenum phosphide single crystal of the exemplary embodiment by using XPS. As a result of analyzing molybdenum (Mo), phosphorus (P), and gallium (Ga) spectra, in a molybdenum 3d spectrum, a 230.97 eV peak and a 227.83 eV peak corresponding to a molybdenum element (molybdenum bonded to phosphorus) of molybdenum phosphide were confirmed; and in a phosphorus 2p spectrum, a 129.03 eV peak and a 129.92 eV peak corresponding to a phosphorus element (phosphorus bonded to molybdenum, P 2p_{3/2} and P 2p_{1/2}) of molybdenum phosphide were confirmed (see Panels (j) and (k) of FIG. 2). In addition, it was confirmed through the gallium (Ga) spectrum that the molybdenum phosphide single crystal of the exemplary embodiment was synthesized with high purity.

### 2) Electrochemical Catalytic Performance Analysis of Molybdenum Phosphide Single Crystal According to Crystal Plane

Electrochemical catalyst performance according to a crystal plane of the molybdenum phosphide single crystal of the exemplary embodiment was evaluated. Oxygen reduction reaction (ORR) analysis of the molybdenum phosphide pillar single crystal and the molybdenum phosphide nanoplate single crystal of the exemplary embodiment was performed under the condition of 0.1 M KOH saturated with oxygen (O₂) by using a rotating ring disk electrode (RRDE).

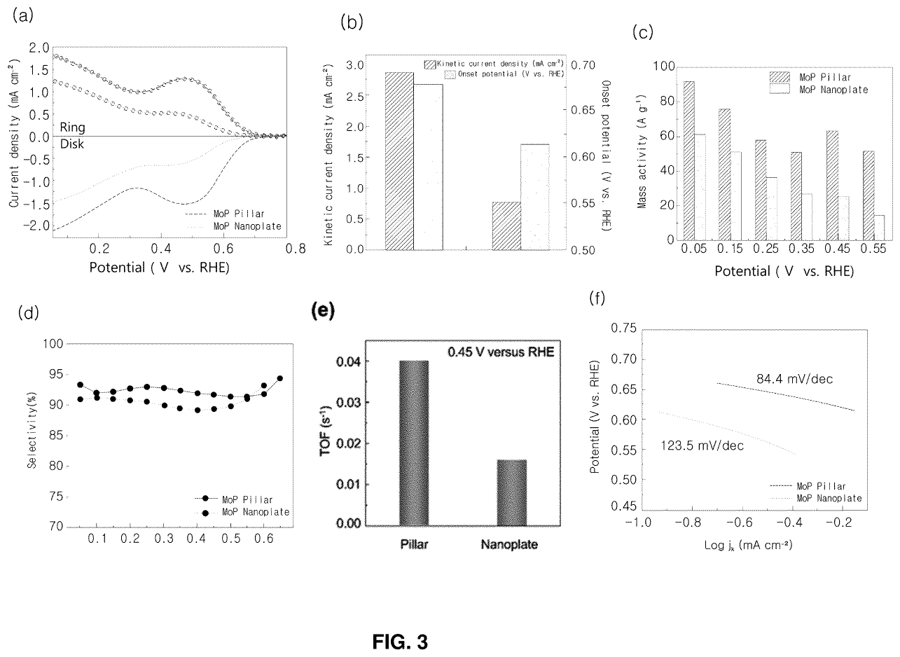

FIG. 3 shows results of analyzing electrochemical oxygen reduction reaction performance related to hydrogen peroxide production according to a crystal plane of the molybdenum phosphide single crystal of the exemplary embodiment. Panel (a) shows results of analyzing oxygen reduction reaction (ORR) performance and hydrogen peroxide sensing current density for a molybdenum phosphide pillar single crystal and a molybdenum phosphide nanoplate single crystal under conditions of 0.1 M KOH saturated with oxygen (O₂) and a sweep rate of 10 mV/s. A hydrogen peroxide current was calculated through a ring current and a calculated collection efficiency. Panel (b) shows kinetic current density at 0.45 V (vs. RHE) and onset potential at a disk current density of 0.1 mA/cm² for the molybdenum phosphide pillar single crystal and the molybdenum phosphide nanoplate single crystal.

Panel (c) shows mass activity of a 2e⁻ reaction for the molybdenum phosphide pillar single crystal and the molybdenum phosphide nanoplate single crystal.

Panel (d) shows hydrogen peroxide selectivity of the molybdenum phosphide pillar single crystal and the molybdenum phosphide nanoplate single crystal.

Panel (e) shows a result of analyzing turnover frequency (TOF) of the molybdenum phosphide pillar single crystal and the molybdenum phosphide nanoplate single crystal.

Panel (f) shows Tafel plots related to hydrogen peroxide production of the molybdenum phosphide pillar single crystal and the molybdenum phosphide nanoplate single crystal. The Tafel plots have been subjected to mass transfer correction.

Panel (a) of FIG. 3 shows a linear sweep voltammetry (LSV) polarization curve for the molybdenum phosphide single crystal of the exemplary embodiment. A solid line represents oxygen reduction current measured at a disk electrode, and a dotted line represents hydrogen peroxide (H₂O₂) oxidation current measured at a ring electrode. It is possible to analyze the efficiency of an oxidation reduction reaction (ORR) process through the oxygen reduction current, and it is possible to analyze the degree of production of hydrogen peroxide through the hydrogen peroxide (H₂O₂) oxidation current.

As a result of the analysis, it has been confirmed that the hydrogen peroxide oxidation current (1.28 mA/cm² vs RHE at 0.45 V) of the molybdenum phosphide pillar single crystal of the exemplary embodiment is 2.6 times greater than the hydrogen peroxide oxidation current (0.49 mA/cm² vs RHE) of the molybdenum phosphide nanoplate single crystal. As a result of calculating kinetic current density for hydrogen peroxide production by correcting the mass transport limitations with the Koudecay-Levich equation, it was confirmed that the kinetic current density (2.85 mA/cm² vs RHE at 0.45 V) of the molybdenum phosphide pillar single crystal was higher than the hydrogen peroxide oxidation current (0.77 mA/cm² vs RHE) of the molybdenum phosphide nanoplate single crystal (see Panel (b) of FIG. 3). In addition, the molybdenum phosphide pillar single crystal exhibited a lower oxidation reduction reaction overpotential than the molybdenum phosphide nanoplate single crystal, and it was confirmed that the onset potential of the molybdenum phosphide pillar single crystal was 0.61 V (Vs. RHE), whereas the onset potential of the molybdenum phosphide nanoplate single crystal was 0.68 V (vs. RHE). Therefore, it is determined that the molybdenum phosphide pillar single crystal exhibits significantly higher 2e⁻ oxidation reduction reaction mass activity than the molybdenum phosphide nanoplate single crystal in the potential range of 0.05 V to 0.55 V (vs. RHE).

The above results of oxidation reduction reaction analysis indicate that the molybdenum phosphide pillar single crystal selectively produces hydrogen peroxide through a 2e⁻ oxidation reduction reaction pathway, and exhibits a hydrogen peroxide selectivity of more than 92% at 0.45 V (vs. RHE) (see Panel (d) of FIG. 3). The above results indicate that among planes of molybdenum phosphide, a (101̅0) surface exhibits better electrocatalyst performance than a (0001) surface, and indicate that since the (101̅0) surface of the molybdenum phosphide pillar single crystal is selectively exposed, thereby optimizing bonding strength of an *OOH intermediate, overpotential is lowered and a kinetics of a 2e⁻ oxidation reduction reaction is improved.

It was confirmed that the turnover frequency (TOF) of the molybdenum phosphide pillar single crystal was 0.04 s⁻¹, which was 2.5 times faster than the turnover frequency (0.016 s⁻¹) of the molybdenum phosphide nanoplate single crystal (see Panel (e) of FIG. 3). The above result indicates that the molybdenum phosphide pillar single crystal has a faster 2e⁻ oxidation reduction reaction rate than the molybdenum phosphide nanoplate single crystal, so that it is determined that the molybdenum phosphide pillar single crystal is expected to have better hydrogen peroxide production efficiency.

As a result of analyzing a Tafel slope of the molybdenum phosphide single crystal, it was confirmed that a Tafel slope (84.4 mV/dec) of the molybdenum phosphide pillar single crystal smaller than a Tafel slope (123.5 mV/dec) of the molybdenum phosphide nanoplate single crystal (see panel (f) of FIG. 3). This indicates that the molybdenum phosphide pillar single crystal has a faster 2e⁻ oxidation reduction reaction rate than the molybdenum phosphide nanoplate single crystal.

### 3) Continuous Hydrogen Peroxide Electrosynthesis of Molybdenum Phosphide Single Crystal

In order to confirm whether the molybdenum phosphide pillar single crystal of the exemplary embodiment can be used as a catalyst for a continuous hydrogen peroxide electrosynthesis reaction, an electrochemical experiment was performed. The electrochemical experiment was performed in a three-electrode setup in a divided H-cell, and 0.1 M KOH saturated with oxygen (O₂) or argon (Ar) was used as an electrolyte. The molybdenum phosphide pillar single crystal was coated on carbon paper at a loading rate of 0.1 mg/cm², and a working electrode (WE) and a counter electrode (CE) were separated by a Nafion membrane to prevent hydrogen peroxide from being decomposed in the counter electrode.

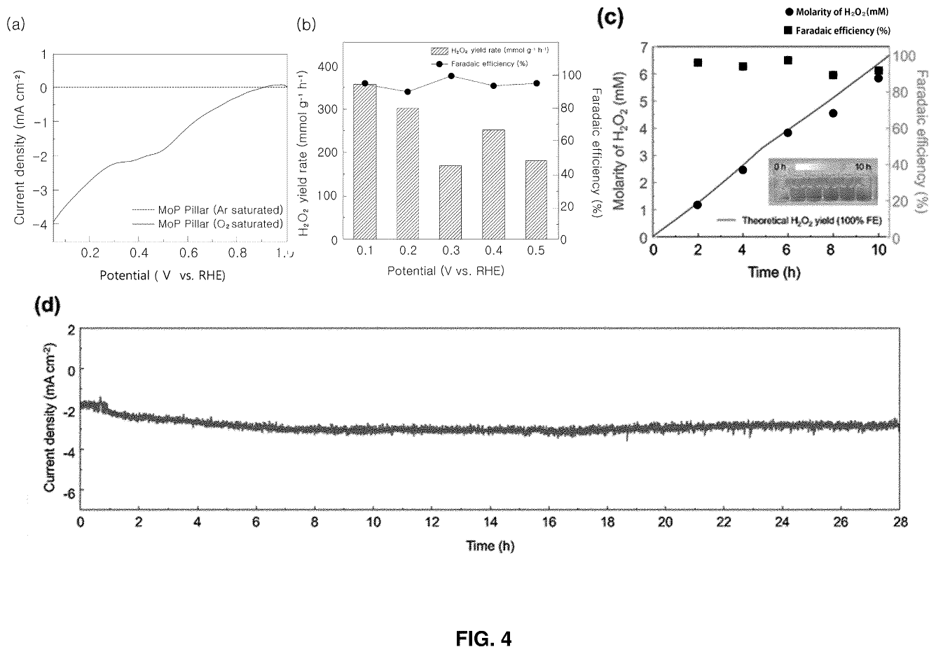

FIG. 4 shows results of using the molybdenum phosphide pillar single crystal of the exemplary embodiment as an electrocatalyst for hydrogen peroxide production in an H-cell. Panel (a) shows a linear sweep voltammetry (LSV) curve of a molybdenum phosphide pillar single crystal catalyst measured in 0.1 M KOH saturated with oxygen (O₂) or argon (Ar); and Panel (b) shows a hydrogen peroxide (H₂O₂) yield rate and a Faradaic efficiency (FE) of the molybdenum phosphide pillar single crystal catalyst measured in the range of 0.1 V to 0.5 V. The electrolyte reacted with a 0.1 M TiOSO₄ solution to produce yellow H₂TiO₄. Panel (c) shows a theoretical hydrogen peroxide yield rate, a detected concentration of hydrogen peroxide, and a Faraday efficiency calculated at 0.1 V for 10 hours, which were derived from a chronoamperometry curve of the molybdenum phosphide pillar single crystal catalyst. The inserted image shows changes in color of a reaction mixture over time. Panel (d) shows results of chronoamperometry analysis of the molybdenum phosphide pillar single crystal catalyst measured at 0.1 V for 28 hours.

As a result of analysis on the linear sweep voltammetry (LSV) curve, it was confirmed that the molybdenum phosphide pillar single crystal exhibited a negligible level of current response in the electrolyte saturated with argon, while exhibiting a significant level of current response in the electrolyte saturated with oxygen. The above result indicates that an oxidation reduction reaction occurred in the electrolyte saturated with oxygen (see panel (a) of FIG. 4).

Hydrogen peroxide was produced through an oxidation reduction reaction in a positive electrode chamber, and Faraday efficiency and hydrogen peroxide yield rate were analyzed. After 1 hour of operation, an electrolyte was obtained and reacted with a 0.1 M TiOSO₄ solution, and as a result of analyzing a hydrogen peroxide yield rate in the range of 0.1 V to 0.5 V, it was confirmed that the hydrogen peroxide yield rate for the molybdenum phosphide pillar single crystal catalyst steadily increased according to overpotential, reaching 359.97 mmol/g at 0.1 V (vs. RHE), and it was confirmed that 7.6 mM of hydrogen peroxide was produced after 10 hours of the reaction. In addition, as a result of analyzing Faraday efficiency of a 2e⁻ oxidation reduction reaction, it was confirmed that 90% or greater was maintained in the entire range (see Panels (b) and (c) of FIG. 4).

As a result of chronoamperometry analysis of the molybdenum phosphide pillar single crystal of the exemplary embodiment, it was confirmed that a current density of 2.8 mA/cm² was maintained at 0.1 V (vs. RHE) for 28 hours. The above results indicate that the molybdenum phosphide pillar single crystal catalyst of the exemplary embodiment has long-term stability as a catalyst in a hydrogen peroxide production process.

### 3. Conclusion

The exemplary embodiment relates to a method for manufacturing a molybdenum phosphide single crystal with a controlled crystal plane by using a liquid-metal-assisted chemical vapor deposition (CVD) method, and an electrochemical catalyst for hydrogen peroxide production using the same.

The exemplary embodiment uses a gallium droplet on molybdenum foil as a growth substrate of the molybdenum phosphide single crystal. When the gallium droplet on the foil is heated to 650° C. to 1100° C., the molybdenum diffuses to the surface of the gallium droplet due to a high surface energy. In this case, when phosphorus (red phosphorus) is heated to 500° C. and conditions of a 250 sccm argon gas flow and a 50 sccm hydrogen gas flow are applied for 30 minutes, a molybdenum phosphide (MoP) single crystal is formed.

It was confirmed that a surface reaction rate was adjusted as a result of changing the synthesis temperature (the heating temperature of the gallium droplet on the foil) of molybdenum phosphide, which resulted in controlling a crystal plane, and as a result, it was confirmed that a molybdenum phosphide nanoplate single crystal with a dominant (0001) crystal plane was synthesized under a synthesis temperature of 650° C. to 850° C., and a molybdenum phosphide pillar single crystal with an exposed (101̅0) crystal plane was synthesized under a synthesis temperature of 900° C. to 1100° C.

As a result of analyzing a method for producing hydrogen peroxide by using the molybdenum phosphide single crystal of the exemplary embodiment as an electrochemical catalyst, it was confirmed that catalyst selectivity and activity were different depending on the type of a crystal plane of the molybdenum phosphide single crystal. For example, when the molybdenum phosphide pillar single crystal characterized by the exposure of the (101̅0) crystal plane was used as a catalyst, hydrogen peroxide production was confirmed to exhibit a selectivity of more than 92% for a 2e⁻ oxidation reduction reaction pathway, and was analyzed to exhibit high kinetic current density. In addition, the molybdenum phosphide pillar single crystal characterized by the exposure of the (101̅0) crystal plane exhibits low overpotential and improved turnover frequency (TOF) and exhibits optimal bonding strength for an *OOH intermediate, and thus is determined to efficiently produce hydrogen peroxide.

In addition, the molybdenum phosphide pillar single crystal characterized by the exposure of the (101̅0) crystal plane maintains a Faradaic efficiency of 90% or greater and maintains stable current density even after 28 hours of continuous operation, and thus is confirmed to have excellent robustness. The above results indicate that when the molybdenum phosphide pillar single crystal characterized by the exposure of the (crystal plane of the exemplary embodiment is used as a catalyst, continuous electrochemical synthesis of hydrogen peroxide is possible.

Therefore, the molybdenum phosphide single crystal with a controlled crystal plane of the exemplary embodiment is expected to replace a typical electrochemical catalyst by being used as an electrocatalyst for hydrogen peroxide production, and is expected to be utilized as a battery, a fuel cell, and other functional devices.

The present invention relates to an electrochemical catalyst composition for hydrogen peroxide production including a molybdenum phosphide crystal and a method for manufacturing the same. The molybdenum phosphide crystal of the present invention is in a single crystal state and has a controlled crystal plane, and thus has the advantage of being usable as an excellent electrochemical catalyst for hydrogen peroxide production. In addition, the manufacturing method of the present invention uses a liquid-metal-assisted chemical vapor deposition method with an optimized temperature, and thus has the advantage in that a molybdenum phosphide single crystal is rapidly grown.

The specific embodiments described in this specification are representative of preferred embodiments or examples of the present invention, and the scope of the present invention is not limited thereby. It will be apparent to those skilled in the art that modifications and other uses of the present invention do not depart from the scope of the invention described in the claims of this specification.

What is claimed is:

1. An electrochemical catalyst composition for hydrogen peroxide production comprising a molybdenum phosphide crystal.

2. The electrochemical catalyst composition of claim 1, wherein the electrochemical catalyst composition for hydrogen peroxide production comprises a molybdenum phosphide crystal, an organic solvent, deionized water, and an ionomer.

3. The electrochemical catalyst composition of claim 1, wherein the molybdenum phosphide crystal is a molybdenum phosphide (MoP) single crystal having an atomic ratio of phosphorus to molybdenum of 1:1.

4. The electrochemical catalyst composition of claim 1, wherein the molybdenum phosphide crystal is either a molybdenum phosphide (MoP) pillar single crystal having a (101̅0) surface, or a molybdenum phosphide (MoP) nanoplate single crystal having a (0001) surface.

5. The electrochemical catalyst composition of claim 1, wherein the molybdenum phosphide crystal is manufactured by a manufacturing method comprising:
a first process of placing a gallium droplet on molybdenum to prepare a gallium-molybdenum substrate;
a second process of heating the gallium-molybdenum substrate to 650° C. to 1100° C.; and
a third process of flowing phosphorus heated to 300° C. to 600° C. over the heated gallium-molybdenum substrate under the condition of a 40 sccm to 300 sccm argon gas or hydrogen gas flow to manufacture a molybdenum phosphide crystal.

6. The electrochemical catalyst composition of claim 5, wherein when the gallium-molybdenum substrate of the second process is heated to 650° C. to 850° C., a molybdenum phosphide pillar single crystal having a (101̅0) surface is manufactured.

7. The electrochemical catalyst composition of claim 4, wherein when the gallium-molybdenum substrate of the second process is heated to 900° C. to 1100° C., a molybdenum phosphide (MoP) nanoplate single crystal having a (0001) surface is manufactured.
